(19) United States
(12) Patent Application Publication
(10) Pub. No.: US 2026/0020192 A1
(43) Pub. Date: Jan. 15, 2026

(54) ADJUSTABLE LIQUID COOLING OF ELECTRONIC DEVICES BY VARIABLE SPEED COOLING PUMPS

(71) Applicant: Flowserve Pte. Ltd., Singapore (SG)

(72) Inventors: Michael Albert Mancuso, Coppell, TX (US); Wendell Wong Shun Yin, Singapore (SG)

(73) Assignee: Flowserve Pte. Ltd., Singapore (SG)

(21) Appl. No.: 19/097,075

(22) Filed: Apr. 1, 2025

Related U.S. Application Data
(63) Continuation-in-part of application No. 18/767,367, filed on Jul. 9, 2024.

(51) Int. Cl. H05K 7/20

(52) U.S. Cl. CPC H05K 7/20381; H05K 7/20318; H05K 7/20327

(57) ABSTRACT

A data center cooling system comprises a cooling loop through which a coolant is caused to flow to a plurality of electronic devices by a variable speed pump under control of a controller. Separate variable speed liquid and vapor pumps are provided in embodiments where the coolant is vaporized by the absorbed heat. In response to changing cooling requirements, the coolant flow rate is adjusted by varying the pump speeds, without reliance on a flow control valve. Cooling is thereby optimized while minimizing pump energy consumption. The cooling loop can be branched into flow paths, each of which can include a separately controlled isolation valve. A plurality of cooling loops can include dedicated, separately controlled variable speed pumps. The pumps can be controlled reactively according to temperature measurements, and/or predictively according to measured electrical current flows to the electronic devices and/or device workload predictions.

### RELATED APPLICATIONS

This application is a continuation in part of U.S. patent application Ser. No. 18/767,367, filed on Jul. 9, 2024, which is included herein by reference in its entirety for all purposes.

### FIELD OF THE INVENTION

The invention relates to cooling of electronic devices, and more particularly to variable cooling of electronic devices by a circulated liquid coolant.

### BACKGROUND OF THE INVENTION

Many electronic devices, including most computers, comprise some sort of cooling mechanism designed to moderate the temperatures of the integrated circuits (ICs) included in the device, as well as the overall temperature within the device housing. For example, most laptop and desktop computers include at least one fan that circulates ambient air throughout the housing interior. In addition, circuits with high power consumption, such as central processing units (CPUs), often include dedicated fans to ensure that they do not overheat.

This “forced air convection” approach is effective for many individual electronic devices having housings that are surrounded by a large volume of ambient air. However, forced air convection may be insufficient for cooling large “clusters” or “arrays” of components or devices that are closely spaced together, and fill most of the volume within a room or building. In particular, cooling of so-called “data centers,” “server farms” artificial intelligence (AI) systems, and “super-computers” (referred to herein collectively as “data centers”) can be challenging. In such cases, cooling of the electronic devices by a circulated liquid coolant can be necessary.

Data centers are one of the most energy-intensive building usage types, consuming from 10 to 50 times as much energy per square foot as a typical commercial office building. Collectively, data centers account for approximately 2% of the total U.S. electricity usage, and this figure is expected to increase as data centers become more numerous, due in part to the rapid increase in artificial intelligence systems.

While much of the energy that is consumed by a data center is due to the power consumed and dissipated by the electronics, a significant amount of energy is also consumed by the cooling systems that are required for removing the dissipated energy from the electronics. Accordingly, there is a need to optimize the energy efficiency of data center cooling systems.

With reference to FIG. 1A, for high power consumption devices, and for high density arrays of electronic devices 100, such as are generally present in data centers, a liquid coolant, such as water, oil, water mixed with ethylene glycol, or some other coolant, is sometimes used to cool the electronic device or devices 100. According to this approach, the coolant is delivered as a cooling liquid to the electronic devices 100 by a liquid coolant pump 106. Heat from the electronic devices 100 is thereby absorbed and delivered to a heat transfer apparatus 108, where the heat is transferred to a radiator, cooling tower, or other heat dissipation device, while the cooled liquid coolant is recycled to the electronic devices 100. The cyclic path that is followed by the coolant, together with any pumps 106, valves, 122, gauges 132, 126 etc. is sometimes referred to herein as a cooling “loop.”

In some applications, the coolant remains a liquid throughout the process, while in the example of FIG. 1A the coolant 102 is vaporized when absorbing heat from the electronic devices 100, and the resulting vaporized coolant 112 is drawn by a vapor suction pump 114 to the heat transfer apparatus 108, where it is “condensed” back to a liquid state 102. In FIG. 1A, the electronic device 100 comprises a printed circuit board 128 on which a plurality of integrated circuit “dies” 130 are mounted. The cooling liquid 102 is circulated through a device cooling manifold 104 that is in direct thermal contact with the dies 130, where it absorbs heat and is vaporized.

A coolant liquid flow control valve 122 can be used to adjust a degree of cooling of the electronic devices 100. In some cases, the valve 122 is operated manually, while in the illustrated example the valve 122 is operated by a valve controller 124, which can actuate the flow control valve 124 according to commands remotely input by a user, or automatically according to temperature measurements or other criteria. The example of FIG. 1A further includes a flow measuring device 132, and a plurality of temperature and pressure gauges or sensors 126.

With reference to the top view of FIG. 1B, a similar approach can be used to cool an array of electronic devices 100. According to this approach, a Coolant Distribution Unit (CDU) comprises inlet 114 and outlet 116 manifolds which circulate the cooling liquid 102 through cooling conduits 118, such as copper pipes, which extend between and/or through the device housings 120 in thermal communication with the electronic devices 100, causing the cooling liquid 102 to absorb heat from the electronic devices 100, and to conduct the heat to an external heat transfer apparatus 108, which in the illustrated example transfers the heat to a cooling tower 110 from which it is dissipated into the atmosphere.

In some applications, the electronic devices 100 that generate the most heat, such as CPUs, are placed in direct thermal contact with the cooling conduits 118, so that they are cooled with the greater efficiency. In various applications, the device housings 120 of FIG. 1B are omitted, and the cooling conduits 118 are in direct thermal contact with the electronic devices 100.

FIG. 1B illustrates a plurality of electronic devices 100 enclosed in separate housings 120 arranged in a horizontal column. In similar applications, the electronic devices 100 are arranged as a grid of devices in perpendicular horizontal rows and columns. According to this approach, each electronic device 100 in FIG. 1B would be replaced by a row, or “bank,” of individual electronic device housings arranged in a horizontal row from left to right. In still other applications, a three-dimensional “matrix” of electronic devices 100 extend horizontally in rows and columns, and vertically in “tiers.”

It will be noted, however, that a similar approach can be used to cool electronic devices 100 that are not arranged in rows and/or columns. It will also be noted that, unless otherwise stated or required by context, terms such as “electronic device,” “electronic component,” and “server” are used generically and interchangeably herein to refer to any electronic element of an electronic system that requires cooling. It will be further noted that terms such as “array” and “device array” are used herein generically to refer to any group of electronic devices and/or components that are to be cooled, regardless of how they are physically arranged.

In the example of FIG. 1B, the coolant remains a cooling liquid after absorbing the heat that is dissipated by the electronic devices 100. Accordingly, a single cooling liquid pump 106 is used to circulate the cooling liquid 104 through the cooling conduits 118, and then through a heat transfer apparatus 108. As in FIG. 1A, a flow control valve 122 can be used to adjust the flow of the cooling liquid 102, and thereby adjust a degree of cooling of the electronic devices 100.

It will be understood, that the heat exchangers 108 and cooling towers 110 that are included in the present drawings are intended to generically represent any external heat transfer and dissipation apparatus, unless otherwise stated or required by context, and are not meant to limit the invention to a specific heat dissipation apparatus design.

For cooling systems such as FIGS. 1A and 1B, significant energy is consumed by the cooling system itself, as well as by the electronic devices. What is needed, therefore, is an electronic device liquid cooling system that can provide optimal cooling to electronic devices while also optimizing the overall energy efficiency of the cooling system.

### SUMMARY OF THE INVENTION

The present invention is an electronic device liquid cooling system that provides optimal cooling to electronic devices while also optimizing the overall energy efficiency of the cooling system.

According to the present invention, rather than operating one or more coolant pumps at fixed operating rates, while possibly adjusting the flow rate of the coolant using one or more flow control valves, the present invention implements one or more variable speed coolant pumps, and adjusts the flow rate of the coolant by varying the operating speeds of the one or more variable speed coolant pumps, without reliance on flow control valves. Accordingly, cooling of the electronic devices is optimized by adjusting the coolant pumping rate according to variable cooling demands, while the energy efficiency of the cooling system is optimized by reducing the operating rate of the variable speed coolant pumps, and thereby reducing the energy consumption of the coolant pumps, when maximum cooling of the electronic devices is not required. In various embodiments, the variable speed coolant pumps are variable frequency pumps.

In some embodiment where the coolant remains a liquid throughout its cooling cycle, the cooling loop comprises only a single variable speed liquid coolant pump. In other embodiments where cooling of the electronic devices causes the coolant to vaporize, the cooling loop comprises at least one variable speed liquid coolant pump and at least one separate variable speed vapor suction pump. In embodiments, an isolation valve is included in the cooling loop, for example to meet safety requirements.

In embodiments, all of the electronic devices are cooled by a single cooling loop, while in other embodiments a plurality of cooling loops are implemented, each having at least one dedicated variable speed coolant pump. By separately adjusting the coolant flow rates in a plurality of cooling loops, specific racks, set of racks, set of chips in a rack, and/or specific chipsets can be targeted with the amount of cooling that is needed, rather than increasing the cooling of all of the electronic devices due to the needs of one sub population that may require maximum cooling.

Similarly, in embodiments, at least one of the cooling loops is branched, having a plurality of flow paths, and in some of these embodiments, isolation valves included in the flow paths are opened and closed so as to concentrate the cooling where it is needed among the electronic devices.

In embodiments, at least one of the cooling loops comprises redundant variable speed pumps configured such that, in case of a pump failure, the operating speeds of the remaining pumps can be increased in compensation.

In various embodiments, adjustment of the operating speeds of the variable speed pumps is reactive, predictive, or both. In some reactive embodiments, the controller receives temperature measurements from one or more locations within an array of electronic devices. In some of these embodiments, at least one of the temperature measurements is provided by a sensor that is integral to an integrated circuit (IC), such as a central processing unit (CPU), and is configured to report a temperature of the IC. Other embodiments include at least one temperature sensor configured to measure a local temperature of the coolant or ambient air.

In some predictive embodiments, the controller is able to adjust the operating speeds of the coolant pumps in advance of any actual changes in electronic device temperature, and in some embodiments also in advance of any actual changes in power consumption by the electronic devices, thereby minimizing or avoiding temperature fluctuations of the electronic devices, and providing increased longevity and improved operational stability of the devices. In some of these embodiments, changes in the heat output of the electronic devices are anticipated by monitoring the amount of current that is drawn by at least one of the electronic devices, such as by one or more servers. This approach is predictive, in that an increase in current usage, and a consequent increase in heat dissipation, generally precedes the resultant rise in device temperature.

In other embodiments where predictive control is implemented, local variations in heat generation within the device array are predicted according to anticipated changes in the workloads that each electronic device will be subjected to. For example, an anticipated workload can be inferred from network activity, and/or on from an internal server scheduler that queues tasks to be performed by the electronic devices. Both are normally precursors to an incoming request for processing of data that will result in a spike in the activity of a server or other electronic device, and hence an increase in heat dissipation.

The present invention is a cooling system configured to cool a plurality of electronic devices. The cooling system comprises a controller, at least one cooling loop through which a coolant can flow as a liquid into proximity and thermal communication with the electronic devices, thereby absorbing heat from the electronic devices, a heat transfer apparatus configured to remove the absorbed heat from the coolant, and a variable speed liquid coolant pump configured to cause the coolant to flow through the cooling loop. The controller is configured to adjust a liquid coolant pump operating speed of the variable speed liquid coolant pump, thereby varying a flow rate of the coolant through the cooling loop, according changes in cooling requirements of the electronic devices.

In embodiments, the cooling system is configured to ensure that the coolant remains in a liquid state after absorbing the heat from the electronic devices.

In any of the above embodiments, the cooling system can be configured to allow the coolant to vaporize due to absorbing the heat from the electronic devices, the heat transfer apparatus can be a condenser configured to accept the vaporized coolant and return the coolant to the liquid state, and the cooling system can further include a variable speed vapor suction pump having a vapor suction pump operating speed that is controlled by the controller, the variable speed vapor suction pump being configured to draw the vaporized coolant from the electronic devices and direct the vaporized coolant to the condenser.

In any of the above embodiments, the variable speed liquid coolant pump can be a variable frequency pump.

In any of the above embodiments, the cooling loop can further include an isolation valve configured to stop the flow of the coolant through the cooling loop.

In any of the above embodiments, the cooling system can include a plurality of cooling loops and a corresponding plurality of variable speed liquid coolant pumps under control of the controller, each of the cooling loops being associated with a corresponding one of the plurality of variable speed liquid coolant pumps, each of the cooling loops being configured to direct the coolant into proximity and thermal communication with a corresponding subset of the electronic devices. In some of these embodiments, the controller is configured to adjust the operating rates of the variable speed liquid coolant pumps according to changes in cooling requirements of each of the subsets of the electronic devices. In any of these embodiment, the cooling system can be configured to allow the coolant to vaporize due to absorbing the heat from the electronic devices, the heat transfer apparatus can be a condenser configured to accept the vaporized coolant and return the coolant to the liquid state, each of the cooling loops can further include a variable speed vapor suction pump under control of the controller, and each of the variable speed vapor suction pumps can be configured to draw the vaporized coolant from a respective one of the subsets of the electronic devices and direct the vaporized coolant to the condenser.

Any of these embodiments can further include a plurality of isolation valves, each of the isolation valves being configured to stop the flow of the coolant through a corresponding one of the cooling loops. In some of these embodiments, each of the plurality of isolation valves is under separate control of the controller.

In any of the above embodiments, the cooling loop can include a plurality of branches, each of the branches comprising a flow path configured to direct a corresponding flow of the coolant through the flow path into proximity and thermal communication with a corresponding subset of the electronic devices. Some of these embodiments further include a plurality of isolation valves, each of the isolation valves being configured to stop the flow of the coolant through an associated one of the flow paths. In some of these embodiments, each of the plurality of isolation valves is under separate control of the controller.

In any of the above embodiments, the controller can be configured to receive a temperature measurement from a first temperature sensor proximate the electronic devices. In some of these embodiments, the first temperature sensor is integral to a first electronic device of the plurality of electronic devices, and is configured to measure an internal temperature of the first electronic device.

In any of the above embodiments, the controller can be configured to predict a heat dissipation increase of the electronic devices in advance of a temperature increase therein. In some of these embodiments, the controller is configured to predict the local heat dissipation increase of the electronic devices at least in part according to at least one of: an amount of current flowing through the electronic devices, and an amount of electrical power flowing to the electronic devices. In any of these embodiments, the controller can be configured to predict the heat dissipation increase of the electronic devices at least in part according to a workload prediction that is applicable to the electronic devices. And in some of these embodiments, the workload prediction is inferred from information regarding network activity, and/or information derived from an internal server scheduler that queues tasks to be performed by the electronic devices.

The features and advantages described herein are not all-inclusive and, in particular, many additional features and advantages will be apparent to one of ordinary skill in the art in view of the drawings, specification, and claims. Moreover, it should be noted that the language used in the specification has been principally selected for readability and instructional purposes, and not to limit the scope of the inventive subject matter.

### BRIEF DESCRIPTION OF THE DRAWINGS

FIG. 1A illustrates a single cooling loop of the prior art in which the coolant is vaporized by absorbed heat, and the coolant flow rate is controlled by fixed speed pumps in combination with a flow control valve;

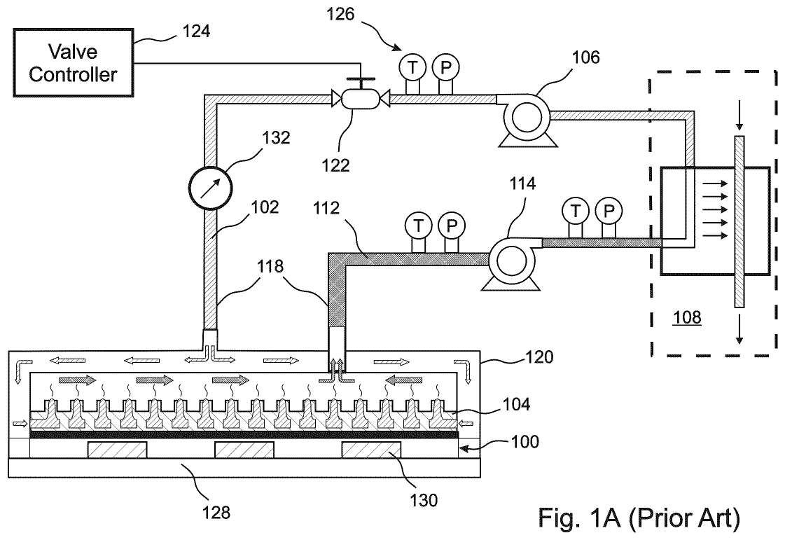

FIG. 1B illustrates a branched cooling loop of the prior art in which the coolant remains liquid throughout the loop;

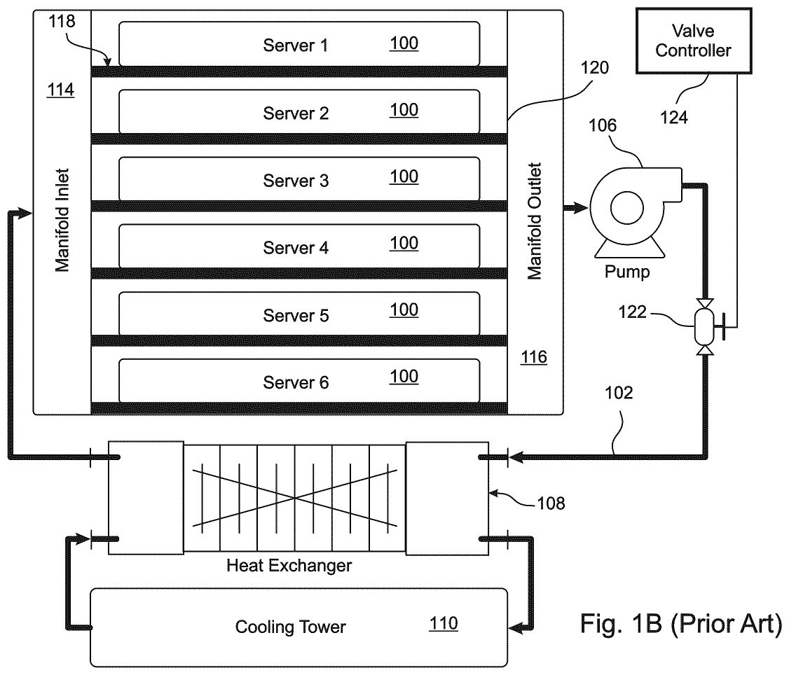

FIG. 2 illustrates a single cooling loop in an embodiment of the present invention in which the coolant is vaporized by absorbed heat, and the coolant flow rate is controlled by controlling the operating speeds of a variable speed liquid coolant pump and a variable speed vapor suction pump, without reliance on a flow control valve;

FIG. 3 illustrates an embodiment that implements a plurality of cooling loops, each cooling loop being similar the cooling loop of FIG. 2; and

FIG. 4 illustrates an embodiment in which a single cooling loop is branched into a plurality of flow paths, each including a dedicated, remotely controlled isolation valve.

### DETAILED DESCRIPTION

The present invention is an electronic device liquid cooling system that provides optimal cooling to electronic devices, while also optimizing the overall energy efficiency of the cooling system.

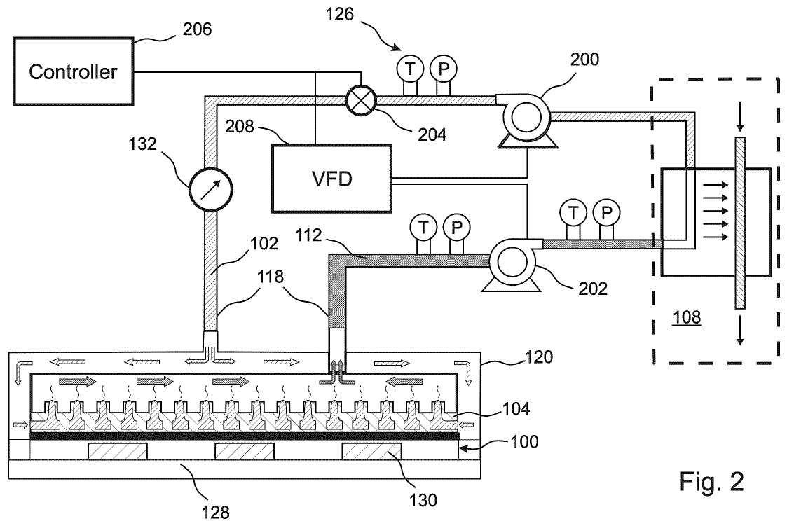

With reference to FIG. 2, rather than operating one or more coolant pumps 106, 114 at fixed operating rates, while possibly adjusting the coolant flow rate(s) using one or more flow control valves 122, the present invention implements one or more variable speed coolant pumps 200, 202, and adjusts the coolant flow through the cooling conduits 118 by varying the operating speeds of the one or more coolant pumps 200, 202, without reliance on flow control valves 122. Accordingly, cooling of the electronic devices 100 is optimized by adjusting the coolant pumping rate through a cooling loop according to variable cooling demands, while the energy efficiency of the cooling system is optimized by reducing the pump operating rates, and thereby reducing the energy consumption of the pumps 200, 202, whenever maximum cooling is not required. In the embodiment of FIG. 2, the variable speed pumps 200, 202 are variable frequency pumps that are controlled by a variable frequency drive (VFD) 208.

In some embodiment where the coolant remains a liquid throughout its cooling cycle, the cooling loop comprises only a single variable speed liquid coolant pump 200. In the embodiment of FIG. 2, cooling of the electronic devices 100 causes the coolant 102 to vaporize 112. Accordingly, the illustrated cooling loop comprises at least one variable speed liquid coolant pump 200 and at least one variable speed vapor suction pump 202. The embodiment of FIG. 2 also comprises an isolation valve 204 that is included to meet safety requirements.

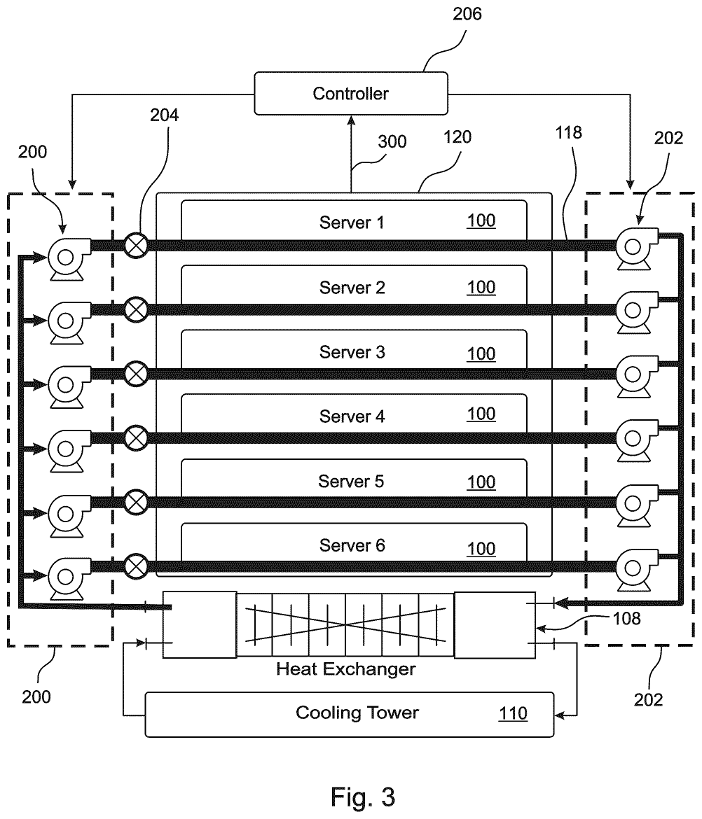

In the embodiment of FIG. 2, all of the electronic devices 100 are cooled by a single cooling loop. With reference to FIG. 3, in other embodiments a plurality of cooling loops are implemented, each comprising at least one cooling conduit 118, and each comprising at least one dedicated variable speed coolant pump 200. In the illustrated embodiment, the cooling liquid 102 is vaporized as it cools the electronic devices 100. Accordingly, the embodiment of FIG. 3 comprises a dedicated liquid coolant pump 200 and a dedicated coolant vapor suction pump 202 for each of the cooling conduits 118. By separately adjusting the operating speeds of the variable speed coolant pumps 200, 202, and thereby separately adjusting the coolant flow rates in the cooling conduits 118, specific racks, set of racks, set of chips in a rack, and/or specific chipsets can each be targeted with an optimal amount of cooling, rather than increasing the cooling of all of the electronic devices 100 due to the needs of one sub-population that may require maximum cooling.

Embodiments include redundant variable speed pumps 200, 202 configured such that, in case of a pump failure, the operating speeds of the remaining pumps can be increased in compensation. In some of these embodiments, failure of a vapor suction pump 202 included in a cooling loop can be compensated by increasing the operating speed of a liquid coolant pump 200 that is also included in the cooling loop, and vice versa.

In various embodiments, adjustment of the operating speeds of the variable speed coolant pumps 200, 202 is reactive, predictive, or both. The embodiment of FIG. 3 implements reactive adjustment of the coolant pumps 200, 202. according to temperature data 300 received by the controller 206 from one or more locations within an array of electronic devices 100. In various embodiments sensors located near or within the electronic devices 100 provide the temperature data. In various embodiments, at least some of the temperature data is provided by a sensor that is integral to an integrated circuit (IC), such as a central processing unit (CPU), and is configured to report a temperature of the IC. Other embodiments include at least one temperature sensor configured to measure a local temperature of the coolant or ambient air.

Predictive control of the variable speed pumps, as is implemented in some embodiments, enables the speeds of the coolant pumps 200, 202 to be adjusted in advance of any actual changes in temperature, and in some embodiments also in advance of any actual changes in power consumption by the electronic devices 100, thereby minimizing or avoiding temperature fluctuations of the electronic devices 100, and providing increased longevity and improved operational stability of the devices 100. In some of these embodiments, changes in the heat output of the electronic devices 100 are anticipated by monitoring the amount of current that is drawn by at least one of the electronic devices 100, such as one or more servers. This approach is predictive, in that an increase in current usage, and a consequent increase in heat dissipation, generally precedes the resultant rise in device temperature.

In other embodiments where predictive control is implemented, local variations in heat generation of the electronic devices 100 are predicted according to anticipated changes in the workloads that each electronic device 100 will be subjected to. For example, an anticipated workload can be inferred from network activity, and/or on from an internal server scheduler that queues tasks to be performed by the electronic devices. Both are normally precursors to an incoming request for processing of data that will result in a spike in the activity of a server or other electronic device 100, and hence an increase in heat dissipation.

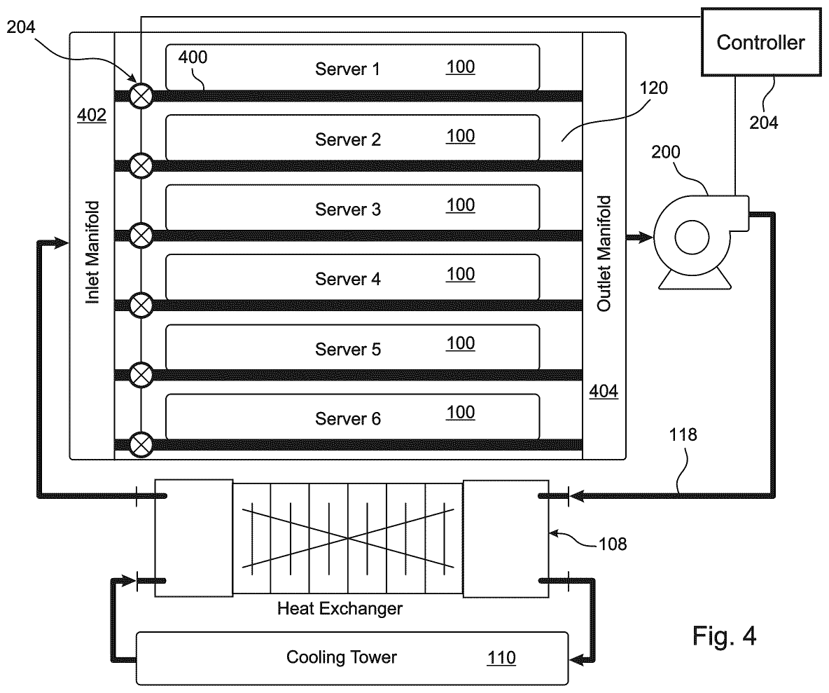

With reference to FIG. 4, in embodiments at least one of the cooling loops is branched, having a plurality of flow paths 400, and in some of these embodiments, isolation valves 204 included in the flow paths 400 are opened and closed to cause the coolant to flow only through those flow paths 400 where it is needed. In the embodiment of FIG. 4, the coolant is not vaporized when cooling the electronic devices 100, such that only one variable speed liquid cooling pump 200 is implemented. The liquid coolant 102 is delivered to an inlet manifold 402 which divides the coolant flow among the plurality of flow paths 400. After cooling the electronic devices 100, the liquid coolant 102 flows into an outlet manifold 404, which combines the flows from all of the flow paths 400 and directs the combined flow to the liquid coolant pump 200, and thence to the heat transfer apparatus 108.

The foregoing description of the embodiments of the invention has been presented for the purposes of illustration and description. Each and every page of this submission, and all contents thereon, however characterized, identified, or numbered, is considered a substantive part of this application for all purposes, irrespective of form or placement within the application. This specification is not intended to be exhaustive or to limit the invention to the precise form disclosed. Many modifications and variations are possible in light of this disclosure.

Although the present application is shown in a limited number of forms, the scope of the disclosure is not limited to just these forms, but is amenable to various changes and modifications. The present application does not explicitly recite all possible combinations of features that fall within the scope of the disclosure. The features disclosed herein for the various embodiments can generally be interchanged and combined into any combinations that are not self-contradictory without departing from the scope of the disclosure. In particular, the limitations presented in dependent claims below can be combined with their corresponding independent claims in any number and in any order without departing from the scope of this disclosure, unless the dependent claims are logically incompatible with each other.

What is claimed is:

1. A cooling system configured to cool a plurality of electronic devices, the cooling system comprising:
a controller;
at least one cooling loop through which a coolant can flow as a liquid into proximity and thermal communication with the electronic devices, thereby absorbing heat from the electronic devices;
a heat transfer apparatus configured to remove the absorbed heat from the coolant; and
a variable speed liquid coolant pump configured to cause the coolant to flow through the cooling loop;
wherein the controller is configured to adjust a liquid coolant pump operating speed of the variable speed liquid coolant pump, thereby varying a flow rate of the coolant through the cooling loop, according changes in cooling requirements of the electronic devices.

2. The cooling system of claim 1, wherein the cooling system is configured to ensure that the coolant remains in a liquid state after absorbing the heat from the electronic devices.

3. The cooling system of claim 1, wherein:
the cooling system is configured to allow the coolant to vaporize due to absorbing the heat from the electronic devices;
the heat transfer apparatus is a condenser configured to accept the vaporized coolant and return the coolant to the liquid state; and
the cooling system further comprises a variable speed vapor suction pump having a vapor suction pump operating speed that is controlled by the controller, the variable speed vapor suction pump being configured to draw the vaporized coolant from the electronic devices and direct the vaporized coolant to the condenser.

4. The cooling system of claim 1, wherein the variable speed liquid coolant pump is a variable frequency pump.

5. The cooling system of claim 1, wherein the cooling loop further comprises an isolation valve configured to stop the flow of the coolant through the cooling loop.

6. The cooling system of claim 1, wherein the cooling system comprises a plurality of cooling loops and a corresponding plurality of variable speed liquid coolant pumps under control of the controller, each of the cooling loops being associated with a corresponding one of the plurality of variable speed liquid coolant pumps, each of the cooling loops being configured to direct the coolant into proximity and thermal communication with a corresponding subset of the electronic devices.

7. The cooling system of claim 6, wherein the controller is configured to adjust the operating rates of the variable speed liquid coolant pumps according to changes in cooling requirements of each of the subsets of the electronic devices.

8. The cooling system of claim 6, wherein:
the cooling system is configured to allow the coolant to vaporize due to absorbing the heat from the electronic devices;
the heat transfer apparatus is a condenser configured to accept the vaporized coolant and return the coolant to the liquid state;
each of the cooling loops further comprises a variable speed vapor suction pump under control of the controller; and
each of the variable speed vapor suction pumps is configured to draw the vaporized coolant from a respective one of the subsets of the electronic devices and direct the vaporized coolant to the condenser.

9. The cooling system of claim 6, further comprising a plurality of isolation valves, each of the isolation valves being configured to stop the flow of the coolant through a corresponding one of the cooling loops.

10. The cooling system of claim 9, wherein each of the plurality of isolation valves is under separate control of the controller.

11. The cooling system of claim 1, wherein the cooling loop comprises a plurality of branches, each of the branches comprising a flow path configured to direct a corresponding flow of the coolant through the flow path into proximity and thermal communication with a corresponding subset of the electronic devices.

12. The cooling system of claim 11, further comprising a plurality of isolation valves, each of the isolation valves being configured to stop the flow of the coolant through an associated one of the flow paths.

13. The cooling system of claim 12, wherein each of the plurality of isolation valves is under separate control of the controller.

14. The cooling system of claim 1, wherein the controller is configured to receive a temperature measurement from a first temperature sensor proximate the electronic devices.

15. The cooling system of claim 14, wherein the first temperature sensor is integral to a first electronic device of the plurality of electronic devices, and is configured to measure an internal temperature of the first electronic device.

16. The cooling system of claim 1, wherein the controller is configured to predict a heat dissipation increase of the electronic devices in advance of a temperature increase therein.

17. The cooling system of claim 16, wherein the controller is configured to predict the local heat dissipation increase of the electronic devices at least in part according to at least one of:
an amount of current flowing through the electronic devices; and
an amount of electrical power flowing to the electronic devices.

18. The cooling system of claim 16, wherein the controller is configured to predict the heat dissipation increase of the electronic devices at least in part according to a workload prediction that is applicable to the electronic devices.

19. The cooling system of claim 18, wherein the workload prediction is inferred from information regarding network activity, and/or information derived from an internal server scheduler that queues tasks to be performed by the electronic devices.
